(19) United States
(12) Patent Application Publication
(10) Pub. No.: US 2016/0064316 A1
(43) Pub. Date: Mar. 3, 2016

(54) PACKAGE SUBSTRATE WITH IMPROVED RELIABILITY

(71) Applicants: Burton J. Carpenter, Austin, TX (US); Thomas H. Koschmieder, Austin, TX (US)

(72) Inventors: Burton J. Carpenter, Austin, TX (US); Thomas H. Koschmieder, Austin, TX (US)

(21) Appl. No.: 14/472,836

(22) Filed: Aug. 29, 2014

(51) Int. Cl. H01L 23/498; H01L 23/31; H01L 21/56

(52) U.S. Cl. CPC H01L 23/49811; H01L 21/565; H01L 23/3107; H01L 23/49838

(57) ABSTRACT

A packaged semiconductor device having a package substrate that includes a plurality of electrical contacts on a first major surface and a die positioned on a second major surface. Each of the plurality of electrical contacts includes a perimeter portion. A first subset of the electrical contacts have more than fifty percent of the perimeter portion bounded by a solder mask. A second subset of the electrical contacts have less than fifty percent of the perimeter portion bounded by a solder mask. The die is positioned over only the first subset of the electrical contacts.

### BACKGROUND

1. Field

This disclosure relates generally to semiconductors, and more specifically, to improving the reliability of a packaged semiconductor device that includes a package substrate having solder connections.

2. Related Art

Packaged semiconductor devices include solder connections for forming external connections, such as to a printed circuit board. Due to various thermal and mechanical forces, solder connections can suffer various mechanical failures, which in turn reduce reliability and lifespan of the packaged semiconductor device.

### BRIEF DESCRIPTION OF THE DRAWINGS

The present invention may be better understood, and its numerous objects, features, and advantages made apparent to those skilled in the art by referencing the accompanying drawings.

FIG. 1 illustrates a cross-sectional side view and a corresponding surface view depicting an example packaged semiconductor device that implements the present disclosure, according to some embodiments.

FIG. 2 illustrates a cross-sectional side view depicting an example solder mask defined solder connection, according to some embodiments.

FIG. 3 illustrates a cross-sectional side view depicting an example non-solder mask defined solder connection, according to some embodiments.

FIGS. 4 and 5 illustrate surface views depicting example packaged semiconductor devices that implement the present disclosure, according to some embodiments

FIG. 6 illustrates a cross-sectional side view depicting an example flip chip packaged device that implements the present disclosure, according to some embodiments.

FIGS. 7 and 9 illustrate surface views depicting example solder mask defined pads, according to some embodiments.

FIGS. 8 and 10 illustrate surface views depicting example non-solder mask defined pads, according to some embodiments.

The present invention is illustrated by way of example and is not limited by the accompanying figures, in which like references indicate similar elements, unless otherwise noted. Elements in the figures are illustrated for simplicity and clarity and have not necessarily been drawn to scale.

### DETAILED DESCRIPTION

The following sets forth a detailed description of various embodiments intended to be illustrative of the invention and should not be taken to be limiting.

Due to increasingly stringent reliability criteria expected of packaged semiconductor devices, it is generally desirable to increase the reliability and lifespan of solder connections used in such devices. The present disclosure provides for improving reliability and lifespan of solder connections by using solder mask defined (SMD) pads in a region on a bottom surface of a package substrate that is under a die attached to a top surface (which is opposite the bottom surface) of the package substrate, and non-solder mask defined (NSMD) pads in another region that is not under the die, as described herein. The selected placement of SMD pads and NSMD pads on the package substrate relative to the die results in solder connections that are better able to withstand the different thermal and mechanical forces experienced in the different regions of the package substrate, resulting in increased reliability and lifespan of the solder connections.

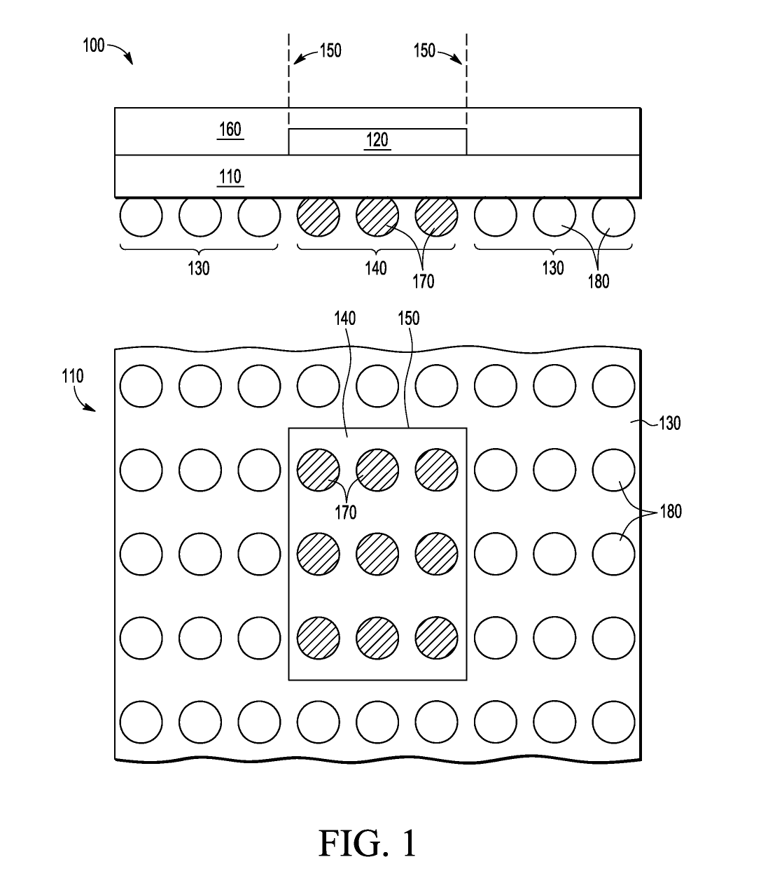

FIG. 1 illustrates a partial cross-sectional side view and a corresponding surface view depicting an example packaged semiconductor device 100 that implements the present disclosure. The cross-sectional side view is located at the top of FIG. 1, which illustrates packaged semiconductor device 100 (also referred to as packaged device 100 or package device 100) that includes a package substrate 110 and a die 120 attached to a top surface of package substrate 110. Die 120 may be attached to the top surface of package substrate 120 using an attachment material (not shown). Packaged device 100 also includes encapsulant 160 surrounding and covering die 120. Die 120 also has a perimeter 150 that follows an outer boundary of die 120. A solder mask defined (SMD) pad region 140 is located in an area on a bottom surface of the package substrate 110 within die perimeter 150, the bottom surface being opposite the top surface of package substrate 110. A non-solder mask defined (NSMD) pad region 130 is located in another area on the bottom surface of the package substrate 110 outside of die perimeter 150. Packaged device 100 also includes a plurality of solder connections (also referred to as a plurality of electrical contacts) attached to the bottom surface of package substrate 110.

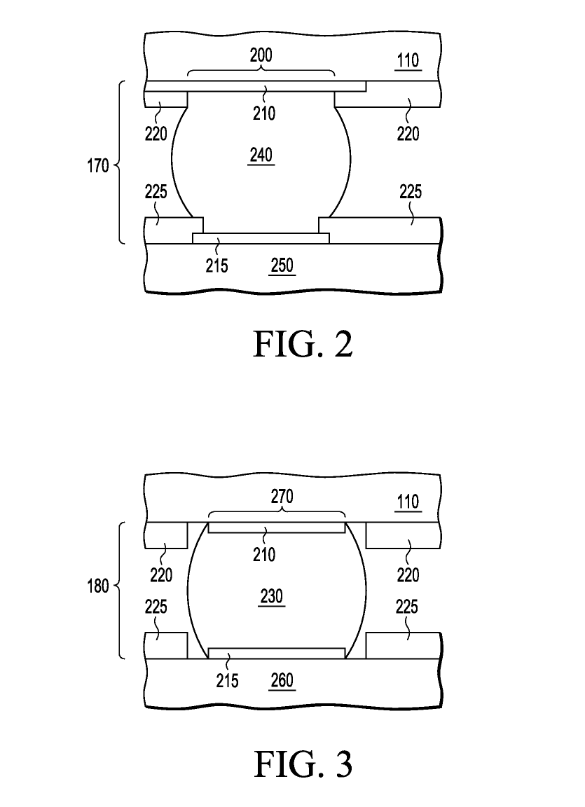

The corresponding surface view is located at the bottom of FIG. 1, which illustrates a bottom surface of package substrate 110, where the plurality of solder connections are attached to the bottom surface of package substrate 110. In the embodiment shown, die perimeter 150 is illustrated near the center of package substrate 110, SMD pad region 140 is illustrated in an area within die perimeter 150, and NSMD pad region 130 is illustrated in an area outside of die perimeter 150. A first subset of solder connections 180 of the plurality of solder connections is located within NSMD pad region 130 (also referred to as a set of NSMD solder connections 180). Each NSMD solder connection 180 includes an NSMD pad on the bottom surface of package substrate 110 within NSMD pad region 130 and solder material joined to the NSMD pad (e.g., a solder joint, solder ball, or other solder connection). An example NSMD solder connection 180 is further discussed below in connection with FIG. 3. A second subset of solder connections 170 of the plurality of solder connections is located within SMD pad region 140 (also referred to as a set of SMD solder connections 170). Each SMD solder connection 170 includes an SMD pad on the bottom surface of package substrate 110 within SMD pad region 130 and solder material joined to the SMD pad (e.g., a solder joint, solder ball, or other solder connection). An example SMD solder connection 170 is further discussed below in connection with FIG. 2.

In some embodiments, an intermediate pad region (not shown) is also included, where the intermediate pad region follows die perimeter 150 between SMD pad region 140 and NSMD pad region 130. In such embodiments, a third subset of solder connections (not shown) of the plurality of solder connections are located within the intermediate pad region. If present, the third subset of solder connections includes NSMD solder connections, SMD solder connections, or both, depending on the design choices implemented in the package substrate. An intermediate pad region is further discussed below in connection with FIG. 5.

In some embodiments, two or more die 120 (not shown) are attached to the top surface of package substrate 110. In some embodiments, die 120 includes a stacked die (e.g., two or more die vertically stacked over the package substrate 110). In embodiments having two or more attached die 120, each attached die 120 has a respective die perimeter 150 and a corresponding SMD pad region 140 on the bottom surface of package substrate 110 located in an area within the respective die perimeter 150 (e.g., underneath the attached die). In such embodiments, one or more NSMD pad regions 130 on the bottom surface of package substrate 110 are located in an area(s) outside of each respective die perimeter 150. In some embodiments, one or more intermediate pad regions may also be located between each SMD pad region and NSMD pad region along one or more respective die perimeters 150.

Examples of the attachment material include polymer adhesives, epoxies, films, and the like. Examples of package substrate 110 include, but are not limited to, a ball grid array (BGA) package substrate, redistributed chip package (RCP) substrate, flip chip package substrate, wire bond BGA package substrate, enhanced wafer level BGA package substrate, fan out wafer level package substrate, and the like. Examples of die 120 include, but are not limited to, an integrated circuit (IC) die, a sensor die, a passive component such as a resistor, a capacitor, an inductor, a battery, an oscillator, and the like, a sensor device, a mechanically rigid object that is stiffer than the package substrate due to having a greater elastic modulus value than the package substrate's modulus value, and the like. Examples of encapsulant 160 include, but are not limited to, mold compound, epoxy, and the like.

FIG. 2 illustrates a partial cross-sectional side view depicting an example solder mask defined (SMD) solder connection 170 located in SMD pad region 140. SMD solder connection 170 includes an SMD pad 200 located on the bottom surface of package substrate 110 and solder material 240. SMD pad 200 includes a metal layer 210 of one or more conductive materials formed on the bottom surface of package substrate 110. SMD pad 200 also includes a solder mask 220 formed on the bottom surface of package substrate 110. Solder mask 220 includes a solder mask opening through which metal layer 210 is exposed. The edge of the solder mask opening forms a boundary around the metal layer 210, preventing solder material 240 from wicking or flowing beyond the boundary. In the embodiment illustrated in FIG. 2, solder mask 220 covers an edge portion of metal layer 210 (e.g., the solder mask opening has a width that is smaller than the width of the metal layer 210) and forms the boundary within an outer edge of metal layer 210. It is noted that solder mask openings often have a cross-sectional area bounded by a circular shape, but may also have a cross-sectional area bounded by a polygonal shape (e.g., triangular, rectangular, octagonal, and the like), a curved shape (e.g., oval), or an amorphous shape (e.g., a shape having an irregular or non-symmetrical boundary).

Solder material 240 is joined to SMD pad 200. In some embodiments, solder material 240 is also joined to a contact pad 215 on a chip carrier 250. Examples of chip carrier 250 include a printed circuit board, mounting structure, and the like. In the embodiment shown, contact pad 215 is also an SMD pad having a solder mask 225 surrounding contact pad 215, although contact pad 215 may be an NSMD pad in other embodiments.

Solder material 240 has a first solder joint at the SMD pad 200 (also referred to as an SMD solder joint) and a second solder joint at contact pad 215. The first solder joint is adjacent to the edge of solder mask 220, where the solder material 240 is “pinched” at the edge of solder mask 220, which introduces stress to the solder joint. In one failure mode, a crack in the first solder joint occurs in response to the stress introduced at one point on the edge of the solder mask 220 and propagates across the first solder joint to other points on the edge of the solder mask 220, resulting in a mechanical failure of the solder connection. Based on experimental data obtained during thermal and mechanical stress tests, SMD solder connections at the edge of a package substrate tend to fail before SMD solder connections located under a die fail, indicating that SMD solder connections better withstand the thermal and mechanical forces experienced by the package substrate under the die.

Examples of conductive materials used for metal layer 210 include, but are not limited to, copper, copper plated with another conductive material such as nickel, gold, tin, and palladium, and the like. It is noted that one or more of the conductive materials may dissolve or develop into an intermetallic material during the soldering process. It is also noted that if an organic solderability protectant (OSP) is used, the OSP disappears during soldering and leaves the conductive materials, such as copper and tin. Examples of solder mask 220 include, but are not limited to, an epoxy, an acrylic material, a polymer, organic material, and the like.

FIG. 7 illustrates a surface view of an example SMD pad 200. In the embodiment shown, solder mask 220 includes a solder mask opening through which a portion of metal layer 210 is exposed. A perimeter 710 is located at the edge of the solder mask opening, which forms a boundary around the exposed metal layer 210. Although a circular solder mask opening is shown, such opening may have a cross-sectional area bounded by some other shape, as discussed above. A portion of the exposed metal layer 210 that is adjacent to perimeter 710 is referred to as a perimeter portion 715 of exposed metal layer 210. FIG. 7 illustrates some embodiments where solder mask 220 fully bounds perimeter portion 715. In other words, perimeter portion 715 is surrounded by solder mask 220 on all sides.

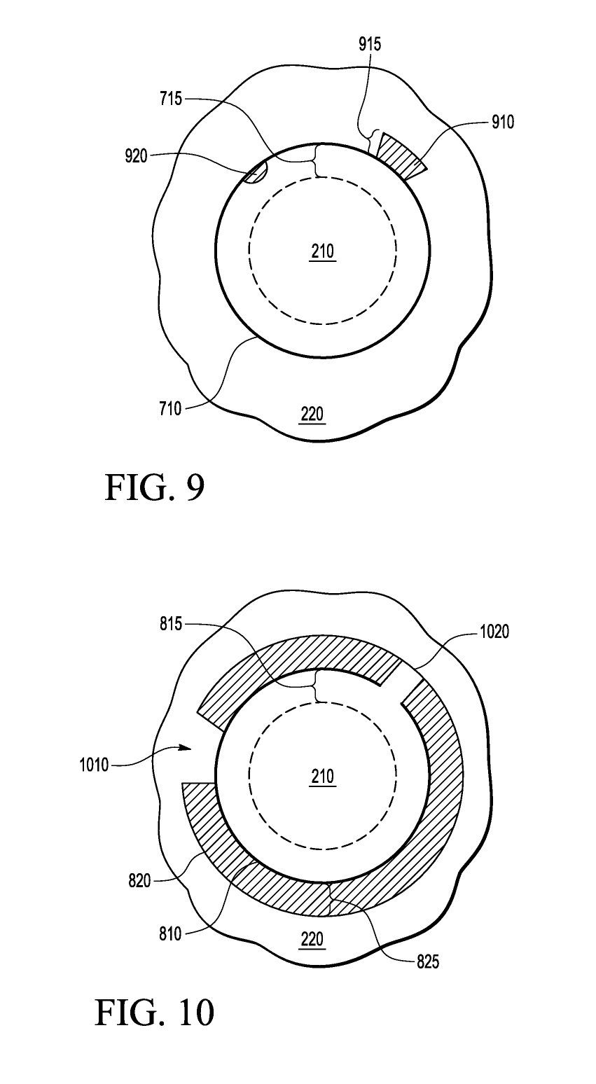

FIG. 9 illustrates a surface view of another example SMD pad 200. FIG. 9 illustrates other embodiments where at least a portion of perimeter portion 715 is not bounded by solder mask 220. In other words, perimeter portion 715 is separated from solder mask 220 by some spacing distance 915, where the separation from solder mask 220 is represented by extended solder mask opening 910. An underlying edge of metal layer 210, as well as underlying material (e.g., an epoxy layer or some dielectric layer) of package substrate 110 beyond the edge of metal layer 210, may be exposed in extended solder mask opening 910. Also, metal layer 210 may include holes or voids, represented as void 920, which in turn may also expose underlying material (e.g., an epoxy layer or some dielectric layer) of package substrate 110.

Although extended solder mask opening 910 is illustrated as being contiguous, this need not be the case, where instead extended solder mask opening 910 may be non-contiguous along perimeter portion 715 (e.g., into two or more perimeter solder mask openings). It can also be said that extended solder mask opening 910 (such as a contiguous opening or a number of non-contiguous openings) is formed along less than 50% of perimeter 710 (e.g., 49% and less).

In some embodiments, solder mask 220 bounds 100% of perimeter portion 715 (e.g., extended solder mask opening 910 is absent, as shown in FIG. 7). In other embodiments, solder mask 220 bounds at least 50% (e.g., 50% and greater, such as 66%, 75%, and so on) of perimeter portion 715, with the remaining portion of perimeter portion 715 separated from solder mask 220 by spacing distance 915 (e.g., extended solder mask opening 910 is present, as shown in FIG. 9).

FIG. 3 illustrates a partial cross-sectional side view depicting an example non-solder mask defined (NSMD) solder connection 180 located in NSMD pad region 130. NSMD connection 180 includes an NSMD pad 270 located on the bottom surface of package substrate 110 and solder material 230. NSMD pad 270 includes a metal layer 210 of one or more conductive materials formed on the bottom surface of package substrate 110. Examples of the conductive materials and solder material 230 are discussed above. NSMD pad 270 also includes a solder mask 220 formed on the bottom surface of package substrate 110. Solder mask 220 includes a solder mask opening through which metal layer 210 is exposed. The edge of the solder mask opening is separated from metal layer 210 by some spacing distance (e.g., the solder mask opening has a width that is larger than the width of the metal layer 210). The cross-sectional area of a solder mask opening is also discussed above.

Solder material 230 is joined to NSMD pad 270. In some embodiments, solder material 230 is also joined to a contact pad 215 on a chip carrier 260. Examples of a chip carrier are discussed above. In the embodiment shown, contact pad 215 is also an NSMD pad having a solder mask 225 separate from the metal layer by a spacing distance, although contact pad 215 may be an SMD pad in other embodiments.

Solder material has a first solder joint at the NSMD pad 270 (also referred to as an NSMD solder joint) and a second solder joint at contact pad 215. The spacing between solder mask 220 and metal layer 210 allows solder material 230 to wet down the sides of metal layer 210, which reduces the stress introduced at the first solder joint by the edge of the solder mask 220.

FIG. 8 illustrates a surface view of an example NSMD pad 270. In the embodiment shown, a perimeter 810 is located around the edge of metal layer 210. A portion of the metal layer 210 that is adjacent to perimeter 810 is referred to as a perimeter portion 815 of metal layer 210. Solder mask 220 includes a solder mask opening 820 that is separated from metal layer 210 (and from perimeter portion 815) at some point by a spacing distance 825. The underlying material (e.g., an epoxy layer or some dielectric layer) of the package substrate 110 beyond the edge of metal layer 210 may also be exposed within spacing distance 825. FIG. 8 illustrates some embodiments where metal layer 210 is fully exposed in solder mask opening 820 and where perimeter portion 815 is fully unbounded by solder mask 220. In other words, perimeter portion 815 is separated from solder mask 220 by spacing distance 825 on all sides, with some tolerance for remnants of solder mask 220 that are not completely removed, resulting in a narrowed spacing distance 825 at some points. Also, once a solder connection is made to NSMD pad 270, some solder material may cover spacing distance 825. Although a circular solder mask opening 820 is shown, such opening may have a cross-sectional area bounded by some other shape, as discussed above.

FIG. 10 illustrates a surface view of another example NSMD pad 270. FIG. 10 illustrates other embodiments where solder mask 220 bounds at least a portion of perimeter portion 815. In other words, perimeter portion 815 is not separated from solder mask 220 by spacing distance 825 on all sides, but instead is bounded by some portion of solder mask 220, which is represented by extended solder mask portion 1010. Although extended solder mask portion 1010 is illustrated as being contiguous, this need not be the case, where instead extended solder mask portion 1010 may be non-contiguous along perimeter portion 815 (e.g., into two or more extended solder mask portions). It can also be said that extended solder mask portion 1010 (such as a contiguous portion or a number of non-contiguous portions) is formed along less than 50% of the perimeter 810 (e.g., 49% and less).

In some embodiments, solder mask 220 bounds 0% of perimeter portion 815 (e.g., extended solder mask portion 1010 is absent and not formed along perimeter 810, as shown in FIG. 8). In other embodiments, solder mask 220 bounds less than 50% (e.g., 49% and less, such as 33%, 25%, and so on) of perimeter portion 815, with the remaining portion of perimeter portion 815 separated from solder mask 220 by spacing distance 825 (e.g., at least one extended solder mask portion 1010 is present and formed along less than 50% of perimeter 810, as shown in FIG. 10). In still other embodiments, solder mask 220 in combination with the width of conductive trace 1020 bounds less than 50% of perimeter portion 815 (e.g., at least one extended solder mask portion 1010 is present, and the at least one extended solder mask portion and the conductive trace are formed along less than 50% of perimeter 810, as also shown in FIG. 10).

A conductive trace 1020 is also illustrated that is formed from the same conductive material as metal layer 210 and continues under solder mask 220. In one failure mode, a crack in the conductive trace 1020 occurs in response to the stress introduced by solder mask 220 and propagates through the conductive trace 1020, resulting in a mechanical failure of the solder connection. Based on experimental data obtained during thermal and mechanical stress tests, NSMD solder connections located under a die tend to fail before NSMD solder connections located at the edge of a package substrate fail, indicating that NSMD solder connections better withstand the thermal and mechanical forces experienced by the package substrate at the edge of the package substrate.

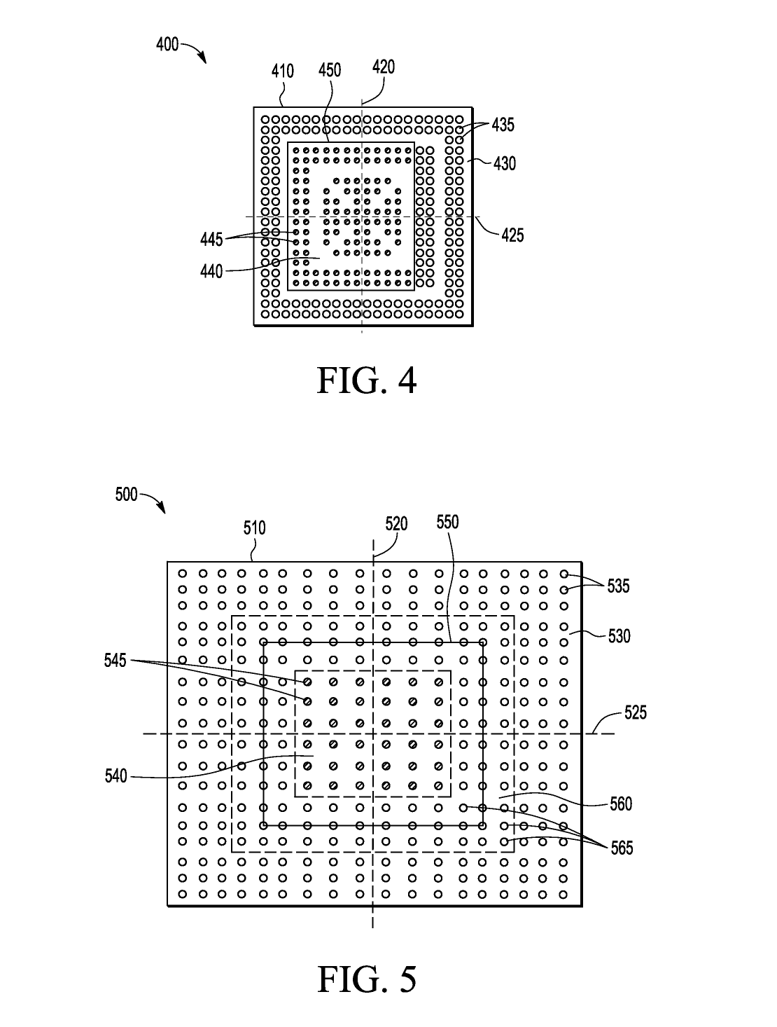

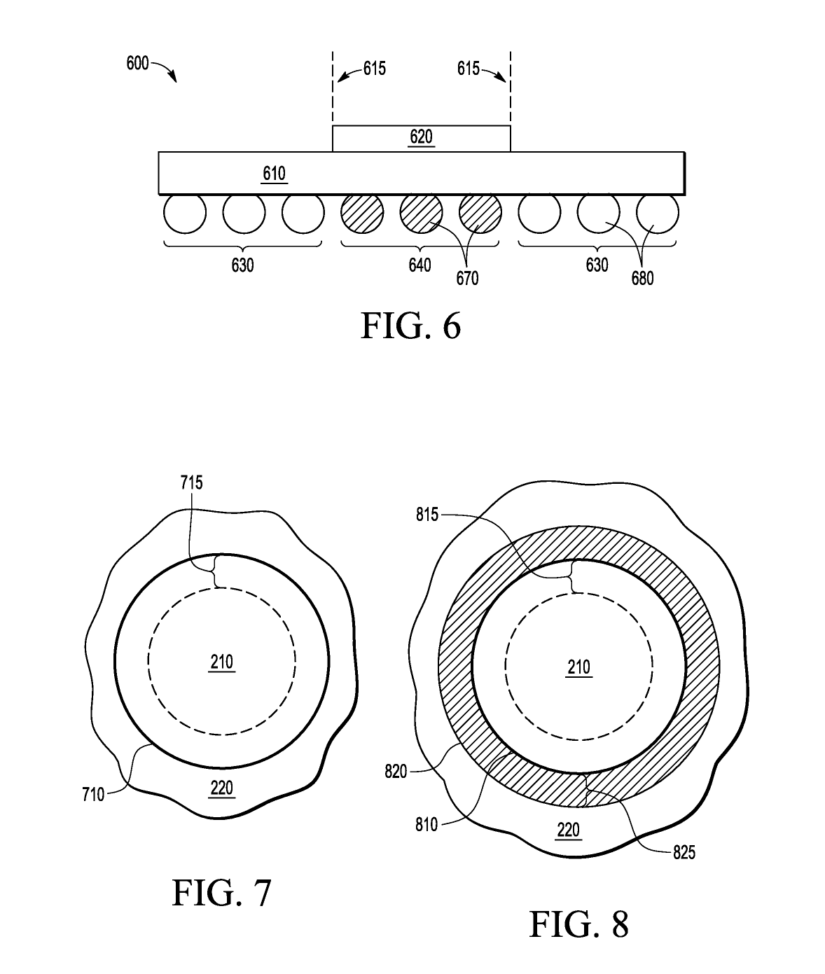

FIG. 4 illustrates a surface view depicting another example packaged semiconductor device. FIG. 4 illustrates a bottom surface of a package substrate 400 that can be used in a packaged semiconductor device like that illustrated in FIG. 1 (or in a flip chip packaged device, as further discussed below in connection with FIG. 6), where a plurality of solder connections are attached to the bottom surface of package substrate 400. The bottom surface is delimited by a package substrate perimeter 410. In the embodiment shown, package substrate perimeter 410 has four edges: a left edge opposite and parallel to a right edge (also referred to as first and second edges), and a top edge opposite and parallel to a bottom edge (also referred to as third and fourth edges), where the top and bottom edges are perpendicular to the left and right edges. The bottom surface of package substrate 400 has a first middle line (or midline) 420 positioned equidistant (or centered) between the left and right edges. Midline 420 runs in parallel to the left and right edges in a first two-dimensional direction (e.g., in a y-axis direction when viewing FIG. 4). The bottom surface also has a second midline 425 that is perpendicular to the first midline 420, the second midline 425 is positioned equidistant (or centered) between the top and bottom edges and runs in parallel to the top and bottom edges in a second two-dimensional direction (e.g., in the x-axis direction when viewing FIG. 4).

A die perimeter 450 is illustrated near the center of the package, which is illustrated as the intersection of midlines 420 and 425. As discussed above, die perimeter 450 corresponds to an outer boundary of a die that is attached to a top surface of the package substrate 400 (which is opposite the bottom surface illustrated in FIG. 4). In the embodiment shown, die perimeter 450 is off-center on the package substrate (e.g., the die perimeter 450 is not centered at the intersection of midlines 420 and 425) in the x-axis direction. It is noted that die perimeter 450 may be off-centered in both the x-axis and y-axis directions. It is noted that the die may be located over nearly any area of the top surface of the package substrate, indicating that the corresponding die perimeter 450 may also be located over nearly any (corresponding) area of the bottom surface of the package substrate, from the center of package substrate 400 to the edge 410 of package substrate, depending on design choices implemented in the package substrate.

Generally, placement of solder connections on a package substrate (also referred to as a layout) is symmetrical and uniform (e.g., each quarter section of package substrate 400 delimited by the midlines 420 and 425 has a common or mirrored pattern of solder connections), but is not required and may in fact be asymmetrical and non-uniform (e.g., a unique pattern of solder connections may be used in one or more quarter sections or across the package substrate). Further, a fully populated or a depopulated arrangement could be used (where a depopulated area is devoid of solder connections). Although a particular placement or layout of solder connections are shown in FIG. 4, such a particular placement or layout is only one non-limiting example, where any suitable placement (e.g., symmetrical or asymmetrical, uniform or non-uniform, populated or depopulated) of the solder connections could be used with the present disclosure.

In the embodiment shown, an NSMD pad region 430 is located in an area outside of die perimeter 450 and includes NSMD solder connections 435, and an SMD pad region 440 is located in an area within die perimeter 450 and includes SMD solder connections 445. Although not shown, an intermediate pad region may be located along die perimeter 450 between SMD pad region 430 and SMD pad region 440, as further discussed below in connection with FIG. 5.

FIG. 5 illustrates a surface view depicting another example packaged semiconductor device. FIG. 5 illustrates a bottom surface of a package substrate 500 that can be used in a packaged semiconductor device like that illustrated in FIG. 1 (or in a flip chip packaged device, as further discussed below in connection with FIG. 6), where a plurality of solder connections are attached to the bottom surface of package substrate 500. The bottom surface is delimited by a package substrate perimeter 510 and has a first midline 520 that runs along a first two-dimensional direction in parallel to first and second edges of the package substrate and a second midline 525 that is perpendicular to the first midline 520 and runs along a second two-dimensional direction in parallel to third and fourth edges of the package substrate (as also discussed above).

In the embodiment shown, a die perimeter 550 is centered on the package substrate, where the center of package substrate 500 is illustrated as the intersection of midlines 520 and 525. As discussed above, die perimeter 550 corresponds to an outer boundary of a die that is attached to a top surface of the package substrate 500 (which is opposite the bottom surface illustrated in FIG. 5). It is noted that the die may be located over nearly any area of the top surface of the package substrate (and may be off-center in one or both x-axis and y-axis directions), indicating that the corresponding die perimeter 550 may also be located over nearly any (corresponding) area of the bottom surface of the package substrate. As discussed above, although a particular placement or layout of solder connections are shown in FIG. 5, such a particular placement or layout is only one non-limiting example, where any suitable placement (e.g., symmetrical or asymmetrical, uniform or non-uniform, populated or depopulated) of the solder connections could be used with the present disclosure.

In the embodiment shown, package substrate 500 includes a fully populated layout of solder connections. In the embodiment shown, an NSMD pad region 530 is located in an area outside of the die perimeter 550 and includes NSMD solder connections 535, and an SMD pad region 540 is located in an area within the die perimeter 550 and includes SMD solder connections 545.

In the embodiment shown, an intermediate pad region 560 is also located along die perimeter 550 between SMD pad region 530 and SMD pad region 540. Intermediate pad region 560 includes one or more solder connections 565, where solder connections 565 include NSMD solder connections, SMD solder connections, or both NSMD and SMD solder connections, depending on the design choices implemented in the package substrate. Design choices implemented in the package substrate take into account the forces exerted on package substrate by a die that is stiffer than the package substrate, which may extend into the package substrate in an area or region beyond the perimeter of the die and affect the solder connections in that region. Design factors may include, but are not limited to, die size, die thickness, package substrate size, encapsulate material modulus, and the like.

In some embodiments, intermediate pad region 560 includes at least one solder connection that is intersected by die perimeter 550 (e.g., die perimeter 550 overlaps the solder connection), which are also referred to as intersected solder connections. In the embodiment illustrated in FIG. 5, package substrate 500 is fully populated with a number of full rows of solder connections (e.g., 18 full rows) that span the bottom surface of package substrate 500. Die perimeter 550 intersects a number of solder connections, with two row segments of intersected solder connections in the y-axis direction and two row segments of intersected solder connections in the x-axis direction. Although rows of solder connections are discussed herein, solder connections may be in formations different than linear rows (e.g., curves, amorphous shapes, and the like).

In other embodiments, intermediate pad region 560 also includes non-intersected solder connections that directly border (or are immediately adjacent to) an intersected solder connection. In the embodiment illustrated in FIG. 5, intermediate pad region 560 also includes one row segment of non-intersected solder connections above and below the row segments of intersected solder connections in the x-axis direction, and one row of non-intersected solder connections to the left and right of the row segments of intersected solder connections in the y-axis direction).

In other embodiments, intermediate pad region 560 may include at most two row segments above and below, and at most two row segments to the left and right of, a row segment of intersected solder connections. In still other embodiments, intermediate pad region 560 includes only one row segment that is either above or below, and only one row segment that is either left or right of, a row segment of intersected solder connections. In still other embodiments, intermediate pad region 560 includes at least one non-intersected solder connection that directly borders (or is immediately adjacent to) die perimeter 550, without necessarily directly bordering an intersected solder connection.

FIG. 6 illustrates a partial cross-sectional side view depicting an example flip chip packaged device 600 that implements the present disclosure. Flip chip packaged device 600 includes a package substrate 610 and a die 620 attached to a top surface of package substrate 610. Die 620 may be attached to the top surface of package substrate 610 using an attachment material (not shown). Examples of package substrate 610, die 620, and attachment material are discussed above. Another example attachment material includes solder. Die 620 has a perimeter 615 that follows an outer boundary of die 620. A solder mask defined (SMD) pad region 640 is located in an area on a bottom surface of the package substrate 610 within the die perimeter 615, the bottom surface being opposite the top surface of package substrate 610. A non-solder mask defined (NSMD) pad region 630 is located in another area on the bottom surface of the package substrate 610 outside of the die perimeter 615.

Flip chip packaged device 600 also includes a plurality of solder connections (also referred to as a plurality of electrical contacts) attached to the bottom surface of package substrate 610. In the embodiment shown, a first subset of solder connections 680 of the plurality of solder connections is located within NSMD pad region 630 (also referred to as a set of NSMD solder connections 680). Each NSMD solder connection 680 includes an NSMD pad on the bottom surface of flip chip package substrate 610 and solder material (e.g., a solder joint, solder ball, or other solder connection) joined to the NSMD pad. An example NSMD solder connection 680 is further discussed above in connection with FIG. 3. A second subset of solder connections 670 of the plurality of solder connections is located within SMD pad region 640 (also referred to as a set of SMD solder connections 670). Each SMD solder connection 670 includes an SMD pad on the bottom surface of flip chip package substrate 610 and solder material joined (e.g., a solder joint, solder ball, or other solder connection) to the SMD pad. An example SMD solder connection 670 is further discussed above in connection with FIG. 2.

In some embodiments, an intermediate pad region (not shown) is also included, where the intermediate pad region lies along perimeter 615 between SMD pad region 640 and NSMD pad region 630. In such embodiments, a third subset of solder connections (not shown) of the plurality of solder connections may also be located within the intermediate pad region. If present, the third subset of solder connections includes NSMD pads, SMD pads, or both, depending on the design choices implemented in the flip chip package substrate. The intermediate pad region is further discussed above in connection with FIG. 5. Flip chip packaged device 600 has a bottom surface view comparable to the surface view illustrated in FIG. 1.

In some embodiments, two or more die 620 (not shown) are attached to the top surface of package substrate 610. In some embodiments, die 620 includes a stacked die (e.g., two or more die vertically stacked over the package substrate 610). In some embodiments, die 620 includes at least one die and a heat spreader lid. In embodiments having two or more attached die 620, each attached die 620 has a respective die perimeter 615 and a corresponding SMD pad region 640 on the bottom surface of package substrate 610 located in an area within the respective die perimeter 615 (e.g., underneath the attached die). In such embodiments, one or more NSMD pad regions 630 on the bottom surface of package substrate 610 are located in an area(s) outside of each respective die perimeter 615. In some embodiments, one or more intermediate pad regions may also be located between each SMD pad region and NSMD pad region along one or more respective die perimeters 615.

By now it should be appreciated that there has been provided embodiments of methods and packaged semiconductor devices for improving reliability and lifespan of solder connections by using solder mask defined (SMD) pads in a region on a bottom surface of a package substrate that is under a die attached to a top surface (which is opposite the bottom surface) of the package substrate, and non-solder mask defined (NSMD) pads in another region that is not under the die.

The present disclosure provides an embodiment of a packaged semiconductor device including a package substrate that includes a plurality of electrical contacts on a first major surface and a die positioned on a second major surface. Each of the plurality of electrical contacts includes a perimeter portion, a first subset of the electrical contacts have more than fifty percent of the perimeter portion bounded by a solder mask, and a second subset of the electrical contacts have less than fifty percent of the perimeter portion bounded by a solder mask, and the die is positioned over only the first subset of the electrical contacts.

One aspect of the above embodiment further provides that the packaged semiconductor device further comprises a carrier coupled to the first and second subsets of the electrical contacts.

Another aspect of the above embodiment further provides that the packaged semiconductor device further comprises one of a group consisting of: a mold compound encapsulating the die and underfill between the die and the package substrate.

Another aspect of the above embodiment further provides that the die is one of a group consisting of an integrated circuit die, a sensor die, a passive component, a sensor device, and a mechanically rigid object.

Another aspect of the above embodiment further provides that the package substrate is one of a group consisting of a redistributed chip package (RCP) substrate, ball grid array package substrate, flip chip package substrate, wire bond ball grid array package substrate, an enhanced wafer level ball grid array, and a fan out wafer level package.

Another aspect of the above embodiment further provides that the packaged semiconductor device further comprises a plurality of conductive traces, each of the conductive traces is connected to the perimeter portion of a corresponding one of the plurality of electrical contacts.

Another aspect of the above embodiment further provides that the plurality of electrical contacts includes solder material.

Another aspect of the above embodiment further provides that the perimeter portion is directly adjacent a connection between a pad on the substrate and a corresponding one of the plurality of electrical contacts.

The present disclosure provides another embodiment of a packaged semiconductor device including a package substrate; a solder mask on the package substrate; a first set of electrical contacts on a first surface of the package substrate, the solder mask is in direct contact with more than fifty percent of a perimeter portion of the first set of electrical contacts; a second set of electrical contacts on the first surface, the solder mask is in direct contact with less than fifty percent of a perimeter portion of the second set of electrical contacts; and a die coupled to a second surface of the package substrate, where the first set of electrical contacts are only located within the perimeter of the die and the second set of electrical contacts are only located outside the perimeter of the die.

One aspect of the above embodiment further provides that the packaged semiconductor device further comprises a carrier coupled to the first and second sets of the electrical contacts.

Another aspect of the above embodiment further provides that the packaged semiconductor device further comprises one of a group consisting of: a mold compound encapsulating the die and underfill between the die and the package substrate.

Another aspect of the above embodiment further provides that the die is one of a group consisting of an integrated circuit die, a sensor die, a passive component, a sensor device, and a mechanically rigid object.

Another aspect of the above embodiment further provides that the package substrate is one of a group consisting of a redistributed chip package (RCP) substrate, ball grid array package substrate, flip chip package substrate, wire bond ball grid array package substrate, an enhanced wafer level ball grid array substrate, and a fan out wafer level package substrate.

Another aspect of the above embodiment further provides that the packaged semiconductor device further comprises a plurality of conductive traces, each of the conductive traces is connected to the perimeter portion of a corresponding one of the plurality of electrical contacts.

Another aspect of the above embodiment further provides that the plurality of electrical contacts include solder material.

Another aspect of the above embodiment further provides that the perimeter portion is directly adjacent a connection between a pad on the substrate and a corresponding one of the plurality of electrical contacts.

The present disclosure provides an embodiment of a method, which includes forming electrical contacts in openings in a solder mask on a package substrate. A first group of the electrical contacts are in contact with more than fifty percent of a perimeter of a corresponding one of the openings, and a second group of the electrical contacts are in contact with less than fifty percent of a perimeter of a corresponding one of the openings. The method also includes coupling a die to another surface of the substrate over only the first group of the electrical contacts.

One aspect of the above embodiment further provides that the method further includes at least one of a group of: encapsulating the die in a mold compound, coupling the electrical contacts to a carrier substrate, and bonding the die to the package substrate.

Another aspect of the above embodiment further provides that the die is one of a group consisting of an integrated circuit die, a sensor die, a passive component, a sensor device, and a mechanically rigid object.

Another aspect of the above embodiment further provides that the package substrate is one of a group consisting of a redistributed chip package (RCP) substrate, ball grid array package substrate, flip chip package substrate, wire bond ball grid array package substrate, an enhanced wafer level ball grid array, and a fan out wafer level package.

The semiconductor substrate described herein can be any semiconductor material or combinations of materials, such as gallium arsenide, silicon germanium, silicon-on-insulator (SOI), silicon, monocrystalline silicon, the like, and combinations of the above.

Because the apparatus implementing the present invention is, for the most part, composed of electronic components and circuits known to those skilled in the art, circuit details will not be explained in any greater extent than that considered necessary as illustrated above, for the understanding and appreciation of the underlying concepts of the present invention and in order not to obfuscate or distract from the teachings of the present invention.

Moreover, the terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

Although the invention is described herein with reference to specific embodiments, various modifications and changes can be made without departing from the scope of the present invention as set forth in the claims below. Accordingly, the specification and figures are to be regarded in an illustrative rather than a restrictive sense, and all such modifications are intended to be included within the scope of the present invention. Any benefits, advantages, or solutions to problems that are described herein with regard to specific embodiments are not intended to be construed as a critical, required, or essential feature or element of any or all the claims.

The term “coupled,” as used herein, is not intended to be limited to a direct coupling or a mechanical coupling.

Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles.

Unless stated otherwise, terms such as “first” and “second” are used to arbitrarily distinguish between the elements such terms describe. Thus, these terms are not necessarily intended to indicate temporal or other prioritization of such elements.

1. A packaged semiconductor device comprising:
a package substrate including a plurality of electrical contacts on a first major surface and a die positioned on a second major surface opposing the first major surface, wherein
edges of the die correspond to a die perimeter on the first major surface, each of the plurality of electrical contacts includes a contact perimeter portion, each electrical contact having located within the die
perimeter has more than fifty percent of the contact perimeter portion bounded by a solder mask, and
electrical contact having located outside of the die perimeter has less than fifty percent of the contact perimeter portion bounded by the solder mask.

2. The packaged semiconductor device of claim 1 further comprising a carrier coupled to the plurality of electrical contacts.

3. The packaged semiconductor device of claim 1 further comprising:
one of a group consisting of: a mold compound encapsulating the die and underfill between the die and the package substrate.

4. The packaged semiconductor device of claim 1 wherein the die is one of a group consisting of an integrated circuit die, a sensor die, a passive component, a sensor device, and a mechanically rigid object.

5. The packaged semiconductor device of claim 1 wherein the package substrate is one of a group consisting of a redistributed chip package (RCP) substrate, ball grid array package substrate, flip chip package substrate, wire bond ball grid array package substrate, an enhanced wafer level ball grid array, and a fan out wafer level package.

6. The packaged semiconductor device of claim 1 further comprising a plurality of conductive traces, each of the conductive traces is connected to the contact perimeter portion of a corresponding one of the plurality of electrical contacts.

7. The packaged semiconductor device of claim 1 wherein the plurality of electrical contacts includes solder material.

8. The packaged semiconductor device of claim 1 wherein the contact perimeter portion is directly adjacent a connection between a pad on the substrate and a corresponding one of the plurality of electrical contacts.

9. A packaged semiconductor device comprising:
a package substrate;
a solder mask on the package substrate;
a first set of electrical contacts on a first surface of the package substrate, the solder mask is in direct contact with more than fifty percent of a contact perimeter portion of the first set of electrical contacts;
a second set of electrical contacts on the first surface, the solder mask is in direct contact with less than fifty percent of a contact perimeter portion of the second set of electrical contacts; and
a die coupled to a second surface of the package substrate, wherein
the second surface opposes the first surface,
edges of the die correspond to a die perimeter on the first surface,
each electrical contact on the first surface located within the die perimeter is included in the first set of electrical contacts, and
each electrical contact on the first surface located outside of the die perimeter is included in the second set of electrical contacts.

10. The packaged semiconductor device of claim 9 further comprising a carrier coupled to the first and second sets of the electrical contacts.

11. The packaged semiconductor device of claim 9 further comprising:
one of a group consisting of: a mold compound encapsulating the die and underfill between the die and the package substrate.

12. The packaged semiconductor device of claim 9 wherein the die is one of a group consisting of an integrated circuit die, a sensor die, a passive component, a sensor device, and a mechanically rigid object.

13. The packaged semiconductor device of claim 9 wherein the package substrate is one of a group consisting of a redistributed chip package (RCP) substrate, ball grid array package substrate, flip chip package substrate, wire bond ball grid array package substrate, an enhanced wafer level ball grid array substrate, and a fan out wafer level package substrate.

14. The packaged semiconductor device of claim 9 further comprising a plurality of conductive traces, each of the conductive traces is connected to the contact perimeter portion of a corresponding one of the plurality of electrical contacts.

15. The packaged semiconductor device of claim 9 wherein the plurality of electrical contacts include solder material.

16. The packaged semiconductor device of claim 9 wherein the contact perimeter portion is directly adjacent a connection between a pad on the substrate and a corresponding one of the plurality of electrical contacts.

17. A method comprising:
forming electrical contacts in openings in a solder mask on a first surface of a package substrate, wherein
the first surface includes a die perimeter that corresponds to a die location on a second surface of the package substrate, the second surface opposing the first surface,
each opening in the solder mask located within the die perimeter is in contact with more than fifty percent of a contact perimeter portion of a corresponding electrical contact, and
each opening in the solder mask located outside of the die perimeter is in contact with less than fifty percent of a contact perimeter portion of a corresponding electrical contact; and
coupling a die to the die location on the second surface of the package substrate, wherein edges of the die correspond to the die perimeter on the first surface.

18. The method of claim 17 further comprising at least one of a group of:
encapsulating the die in a mold compound, coupling the electrical contacts to a carrier substrate, and bonding the die to the package substrate.

19. The method of claim 17 wherein the die is one of a group consisting of an integrated circuit die, a sensor die, a passive component, a sensor device, and a mechanically rigid object.

20. The method of claim 17 wherein the package substrate is one of a group consisting of a redistributed chip package (RCP) substrate, ball grid array package substrate, flip chip package substrate, wire bond ball grid array package substrate, an enhanced wafer level ball grid array, and a fan out wafer level package.
